(19) United States
(12) Patent Application Publication
(10) Pub. No.: US 2025/0137574 A1
(43) Pub. Date: May 1, 2025

(54) DEVICE MOUNT APPARATUSES AND METHODS

(71) Applicant: Belkin International, Inc., El Segundo, CA (US)

(72) Inventors: Mark Joseph Werle, Oceanside, CA (US); Mitchell Davis Suckle, Long Beach, CA (US); Oliver Seil, Long Beach, CA (US); Paer Daniel Saangloef, Los Angeles, CA (US); Steven Lee Lane, Orange, CA (US); Rosanne Shirley Sanfilippo, Los Angeles, CA (US)

(73) Assignee: Belkin International, Inc., El Segundo, CA (US)

(21) Appl. No.: 18/902,036

(22) Filed: Sep. 30, 2024

Related U.S. Application Data
(60) Provisional application No. 63/593,682, filed on Oct. 27, 2023.

(51) Int. Cl. F16M 11/18; F16M 11/10; F16M 11/24; H05K 5/02

(52) U.S. Cl. CPC F16M 11/18; F16M 11/10; F16M 11/242; H05K 5/0234; F16M 2200/068; F16M 2200/08

(57) ABSTRACT

In some embodiments, a device mount may include a base, an arm coupled to the base, a connector coupled to the arm with a rotation joint, a first motor disposed within the base and configured to tilt the connector, facilitated by the rotation joint, and a second motor disposed within the base and configured to rotate the base. In some embodiments, a method may include receiving an indication that a device is coupled to a connector of a device mount, receiving a first signal from the device to move the device mount to track a user or an object in view of one or more of the device's cameras, and in response to the first signal, either actuating a first motor to tilt the connector or actuating a second motor to rotate a base of the device mount to track the user or the object.

### CROSS-REFERENCE TO RELATED APPLICATION

This application claims the benefit of priority under 35 U.S.C. § 119 (e) to prior U.S. Provisional Application No. 63/593,682 filed on Oct. 27, 2023, the entirety of which is incorporated by reference herein.

### FIELD OF DISCLOSURE

The disclosed apparatuses, devices, systems, and methods relate to mounts for electronic devices. More specifically, the present disclosure relates to mounts configured to move and charge electronic devices.

### BACKGROUND

Electronic devices, such as smartphones, tablet computing devices, media players, etc. have gained widespread popularity. These electronic devices typically use direct current (DC) power supplied from a transformer connected to alternating current (AC) power supply. Damage can occur to the conventional power connection in a number of ways. For example, simply inserting the male connector of a power adapter into the female connector of a power adapter can cause damage. Damage can also occur when any of the components are pulled away from other components by a non-axial force while the male and female connectors are still connected together. In order to prevent some of this damage to the electronic devices, charging technology has been updated to a magnetic connector for an electronic device, such as a wireless charging system. Such wireless charging systems, such as Apple, Inc.'s MagSafe® charging system, allow a user to easily place and remove the electronic device from the charger.

Electronic devices today are used in a variety of different settings for video capture, such as live streaming, video conferencing, fitness, enterprise, education, and healthcare. Users are left with few options in order to have free range of motion (i.e., hands-free) while using the video capturing capabilities of these electronic devices. As such, a user is left to his or her own devices to ensure the user is in frame, in focus of the electronic device, and there is sufficient battery life for the duration of the video, which does not allow the user to focus on the content of the video itself.

### SUMMARY

In some embodiments, a device mount may include a base. The device mount may also include an arm coupled to the base. The device mount may also include a connector coupled to the arm with a rotation joint. The device mount may also include a first motor disposed within the base and configured to tilt the connector, facilitated by the rotation joint. The device mount may also include a second motor disposed within the base and configured to rotate the base.

In some embodiments, the device mount may include a band disposed within the arm that is operatively coupled to the first motor and the rotation joint such that actuation of the first motor tilts the connector. In some embodiments, the band may be made of self-lubricating nylon. In some embodiments, the device mount may include a stabilizing member. In some embodiments, the stabilizing member may be a threaded hole configured to receive a threaded fastener on a tripod. In some embodiments, the base may include an operator configured to turn power to the device mount on and off. In some embodiments, the device mount may include one or more lights configured to convey status information. In some embodiments, the connector may include a sensor configured to detect when a device is mounted to the connector. In some embodiments, the connector may be configured to wirelessly charge a device. In some embodiments, the first motor and the second motor may be configured to be actuated by a tracking software running on a device mounted to the connector. In some embodiments, the device mount may include an internal battery and a port configured to receive a power cord from an external power source.

In some embodiments, a device mount may include a base comprising a first portion and a second portion. The device mount may include an arm coupled to the base. The device mount may include a connector coupled to the arm with a rotation joint. The device mount may include a first motor disposed within the base and configured to tilt the connector, facilitated by the rotation joint. The device mount may include a second motor disposed within the base and configured to rotate the second portion of the base.

In some embodiments, the device mount may include a band disposed within the arm that is operatively coupled to the first motor and the rotation joint such that actuation of the first motor tilts the connector. In some embodiments, the band may be made of self-lubricating nylon. In some embodiments, the device mount may include one or more lights configured to convey status information. In some embodiments, the connector may include a sensor configured to detect when a device is mounted to the connector. In some embodiments, the connector may be configured to wirelessly charge a device. In some embodiments, the first motor and the second motor may be configured to be actuated by a tracking software running on a device mounted to the connector.

In some embodiments, a method may include receiving an indication that a device is coupled to a connector of a device mount. The method may include receiving a first signal from the device to move the device mount to track a user or an object in view of one or more of the device's cameras. The method may include in response to the first signal, either actuating a first motor to tilt the connector or actuating a second motor to rotate a base of the device mount to track the user or the object.

In some embodiments, the method may include receiving a second signal from the device to move the device mount to track the user or the object in view of one or more of the device's cameras. The method may include in response to the second signal, either actuating the first motor to tilt the connector or actuating the second motor to rotate the base of the device mount to track the user or the object.

### BRIEF DESCRIPTION OF THE DRAWINGS

The features and advantages of the disclosure will be more fully disclosed in, or rendered obvious by the following detailed exemplary descriptions of embodiments. The detailed descriptions of these exemplary embodiments are to be considered together with the accompanying drawings, wherein like numbers refer to like parts and further wherein:

FIG. 1 illustrates a front view of a device mount in accordance with some embodiments;

FIG. 2 illustrates a partial bottom view of a first portion of a base of a device mount in accordance with some embodiments;

FIG. 3 illustrates a partial rear view of a device mount in accordance with some embodiments;

FIG. 4 illustrates a rear isometric view of a connector of a device mount in accordance with some embodiments;

FIG. 5 illustrates an isometric view of internal components of a device mount in accordance with some embodiments;

FIG. 6 illustrates a rear isometric view of internal components of a device mount in accordance with some embodiments;

FIG. 7 illustrates an exploded view of a device mount in accordance with some embodiments;

FIG. 8 illustrates a block diagram of an example computing device in accordance with some embodiments;

FIG. 9 illustrates an isometric view of a device coupled to a device mount in accordance with some embodiments;

FIG. 10 illustrates a first side view of a device coupled to a device mount in accordance with some embodiments;

FIG. 11 illustrates a second side view of an electronic device coupled to a device mount in accordance with some embodiments;

FIG. 12 illustrates exemplary movement capabilities of a device mount in accordance with some embodiments; and

FIG. 13 illustrates an exemplary method of using a device mount in accordance with some embodiments.

While the present disclosure is susceptible to various modifications and alternative forms, specific embodiments have been shown by way of example in the drawings and will be described in detail herein. It should be understood, however, that the present disclosure is not intended to be limited to the particular forms disclosed. Rather, the present disclosure is to cover all modifications, equivalents, and alternatives falling within the spirit and scope of the disclosure as defined by the appended claims.

### DETAILED DESCRIPTION

This description of the exemplary embodiments is intended to be read in connection with the accompanying drawings, which are to be considered part of the entire written description. It should be understood, however, that the present disclosure is not intended to be limited to the particular forms disclosed and that the drawings are not necessarily shown to scale. Rather, the present disclosure covers all modifications, equivalents, and alternatives that fall within the spirit and scope of these exemplary embodiments. In the description, relative terms such as “lower,” “upper,” “horizontal,” “vertical,” “above,” “below,” “up,” “down,” “top,” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise. The terms “couple,” “coupled,” “operatively coupled,” “operatively connected,” and the like should be broadly understood to refer to connecting devices or components together either mechanically, or otherwise, such that the connection allows the pertinent devices or components to operate with each other as intended by virtue of that relationship.

Specific details are given in the following description to provide a thorough understanding of the embodiments. However, it will be understood by one of ordinary skill in the art that the embodiments may be practiced without these specific details. For example, circuits, systems, networks, processes, and other components may be shown as components in block diagram form in order not to obscure the embodiments in unnecessary details. In other instances, well-known circuits, processes, algorithms, structures, and techniques may be shown without unnecessary detail in order to avoid obscuring the embodiments.

Also, it is note that individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination can correspond to a return of the function to the calling function or the main function.

In some embodiments, a device mount disclosed herein allows a user to create high quality photo and video experiences with an electronic device (e.g., a mobile device's camera application) when integrated with the device mount. According to some embodiments, a device mount allows a user to automatically track subjects in live video across a 360-degree field of view in a horizontal axis, with 90-degrees or more of vertical tilt in a vertical axis. The device mount can take direct control of the stand to customize framing, directly control the motors of the device mount apparatus, and provide the user its own model for tracking other objects. The device mount can be used in many contexts, such as video capture, live streaming, video conferencing, fitness, enterprise, education, and healthcare, just to provide a few non-limiting examples. In some embodiments, the device mount is designed to work with any software app that uses the camera application programming interface (APIs). With the device mount, a user can interact with the space and objects around the user without the need of the user to manually hold or move the electronic device.

For example, Apple's DockKit protocol can be used to interface with the device mount to track the location of objects and/or users that appear in video frames. The DockKit protocol can be implemented by a tracking software, such as a DockKit API. Developer documentation for DockKit is available from Apple for DickKit at, for example, https://developer.apple.com/documentation/. In conjunction with the device mount apparatus, the protocol determines how to best position the electronic device's camera to frame and track objects, with improved person tracking using combined body and face tracking for human subjects. In some embodiments, the tracking software uses some form of machine learning, artificial intelligence, computer vision, or a combination thereof, to track a user and/or objects within the electronic device's camera view.

As an example, the electronic device may be mounted to the device mount. The electronic device then uses one or more of its cameras and image recognition to track people and other recognizable objects to generate positional information. The electronic device may command the device mount, through the DockKit protocol and associated API, to rotate and/or pivot the electronic device in one or more axes. For motion feedback, the electronic device uses: (1) relative positioning data fed back via DockKit; and (2) its own internal inertial measurement unit (IMU) to detect movement in one or more axes. The motion feedback, the relative camera field of view changes, and the tracked object motion changes can all be used as inputs to generate new positional information for the device mount. For moving objects, the electronic device can generate one or more commands for the device to keep the subject, or other object, centered in a specified camera field of view. It will be appreciated that tracking information can also be generated from sources other than an electronic device's cameras.

In use, the device mount can detect the user, place the user in frame, and begin tracking the user using the motorized function of the device mount. If, for example, the user walks over to stack of books in a room to talk about the books, the device mount apparatus in conjunction with software that uses the camera APIs tracks the user throughout the video, allowing the user to focus on the content of the video instead of worrying about the field of view.

Broadly, an embodiment of the device mount disclosed herein provides a charger with 360 degrees of face, body, and movement tracking. The charger can contain a plurality of power options for charging an electronic device. The 360 degrees of face, body, and movement tracking provides 360 degrees of continuous horizontal rotation (i.e., about the y-axis) and up to 180 degrees of vertical tilt (i.e., −90 to +90 degrees from the x-axis).

In some embodiments, the device mount can comprise a base that extends horizontally. Meaning, that in some embodiments, the base can be placed on a horizontal surface while holding an electronic device without tipping over. The base may also include a power outlet prong located on the base. In some embodiments, the power outlet prong is positioned in an extended position, so the device mount apparatus can be plugged into and retained in a wall outlet, such that the base is held in a substantially horizontal position. In some embodiments, the base will house an AC/DC power conversion circuit to change the alternating current to a direct current voltage output appropriate for the electronic device. In other embodiments, the base may be provided with a retractable cord for docking or connection to a remote charging outlet.

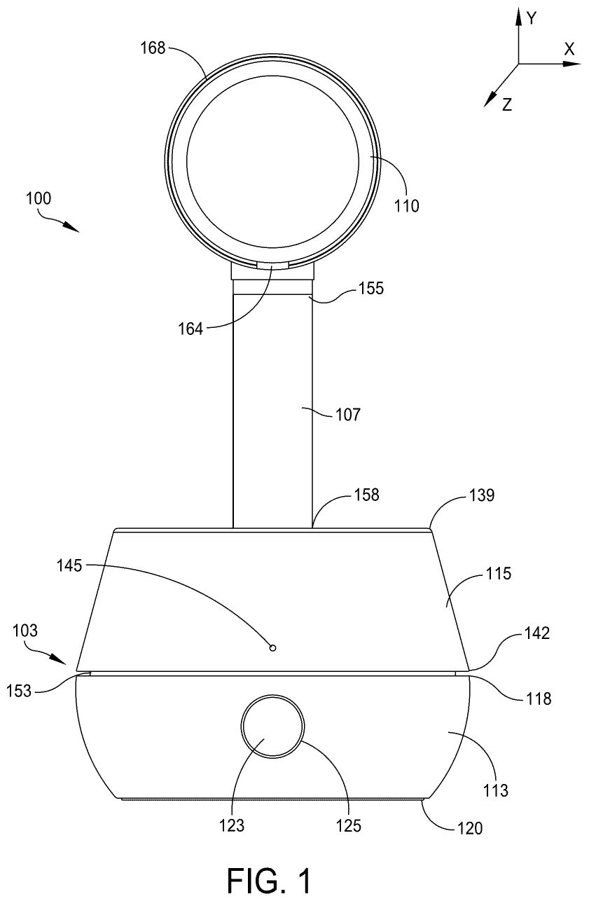

FIG. 1 illustrates a front view of a device mount 100 in accordance with some embodiments. Device mount 100 includes a base 103, an arm 107, and a connector 110. In some embodiments, base 103 includes a first portion 113 and a second portion 115. First portion 113 extends between a first surface 118 and a second surface 120. In some embodiments, first portion 113 includes an operator 123 disposed between first surface 118 and second surface 120. Operator 123 can be configured to turn device mount 100 “on” and “off.” In some embodiments, operator 123 may be a switch, button, lever, or any other suitable operator. For example, operator 123 may be a push-button as illustrated in FIG. 1. In some embodiments, operator 123 may include a light 125 that surrounds operator 123 to indicate an “on”/“off” status of device mount 100. As an example, when device mount 100 is “on” light 125 may be illuminated, and when device mount 100 is “off,” light 125 may be unilluminated. As a second example, when device mount 100 is “on” light 125 may be illuminated with a green light, and when device mount 100 is “off” light 125 may be illuminated with a red light. A person of ordinary skill in the art will appreciate other color and light combinations to indicate a status of device mount 100.

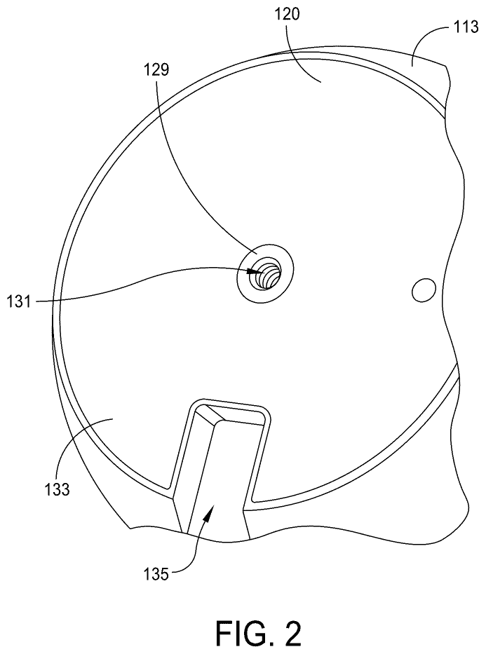

FIG. 2 illustrates a partial bottom view of a first portion 113 of a base 103 of a device mount 100 in accordance with some embodiments. In some embodiments, second surface 120 of first portion 113 includes one or more stabilizing members 129. The one or more stabilizing members 129 may be any suitable mechanism to attach base 103 to a stand or horizontal surface (i.e., along the x-axis as indicated in FIG. 1), such as an adhesive, clip, or threaded aperture. For example, second surface 120 of first portion 113 may define a hole 131 configured to receive a fastener, such as a screw, bolt, etc. In some embodiments, hole 131 is threaded and configured to receive a corresponding threaded fastener. For example, the corresponding threaded fastener may be attached to a stabilizing device, such as a tripod or other stabilizing device. In some embodiments, first portion 113 may be weighted, such that first portion 113 is heavy enough to support device mount 100 while in operation (i.e., with a device, such as a phone or tablet, connected thereto) without the need to attach base 103 to a stand or horizontal surface using one of the one or more stabilizing members 129. In some embodiments, second surface 120 of first portion 113 has an abrasive or non-skid surface 133 (e.g., foam layer, non-skid coating, etc.) configured to prevent base 103 from moving or sliding while device mount 100 is in operation.

Continuing to refer to FIG. 2, second surface 120 of first portion 113 may define a port 135. Port 135 may be configured to receive a power cord that provides power for device mount 100 as will be discussed in more detail below. For example, port 135 may be configured for a lightning, USB, USB-C, or micro-USB connector, just to provide a few non-limiting examples. In some embodiments, port 135 is a lightning port configured to work with a 2.4 amp or a 4.8 amp lightning tip.

Referring back to FIG. 1, second portion 115 extends between a first surface 139 and a second surface 142. In some embodiments, second portion 115 includes one or more lights 145 disposed between first surface 139 and second surface 142. One or more lights 145 can be LEDs positioned to emit light. In some embodiments, the one or more lights 145 has multiple color options configured to convey status information about device mount 100 to a user. For example, the one or more lights 145 can communicate if the product has motion tracking enabled or disabled, if the battery of device mount 100 is charging or fully charged, etc. A person of ordinary skill in the art will appreciate other useful information that can be conveyed to a user through the one or more lights 145.

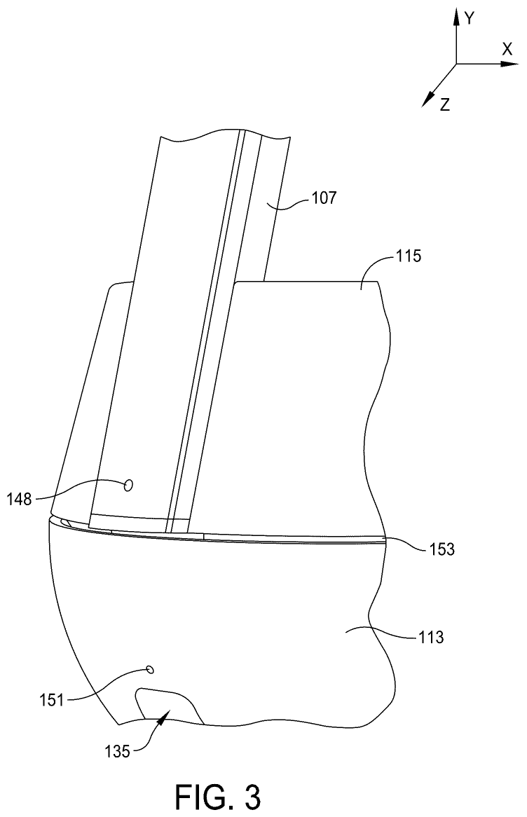

FIG. 3 illustrates a partial rear view of device mount 100 in accordance with some embodiments. In some embodiments, second portion 115 and/or arm 107 includes one or more lights 148 (e.g., LEDs) disposed between first surface 139 and second surface 142, similar to the one or more lights 145, that can be configured to convey status information about device mount 100 to a user. As an example, the one or more lights 148 can be configured to mirror the one or more lights 145. As another example, the one or more 148 may be configured to convey different information than the one or more lights 145. In some embodiments, first portion 113 may include one or more lights 151 disposed between first surface 118 and second surface 120 similar to the one or more lights 145, 148. In certain embodiments, the one or more lights 151 can be configured to convey information about device mount 100 to a user. For example, the one or more lights 151 can be configured to communicate if external power is provided to device mount 100, such as through a power cord plugged in through port 135 as discussed herein.

Referring to FIGS. 1 and 3, first portion 113 and second portion 115 can be configured such that they are rotatable with respect to each other. Meaning, second portion 115 can be configured to rotate about a y-axis while first portion 113 stays still. It will be appreciated that first portion 113 can be configured to rotate about the y-axis while second portion 115 stays still. In some embodiments, device mount 100 can be configured such that first portion 113 and second portion 115 are configured to rotate together about the y-axis. In some embodiments, base 103 further includes a strip 153 disposed between first portion 113 and second portion 115, such as a silicone strip, to minimize noise as the base 103 or second portion 115 is rotated.

First portion 113 and second portion 115 may be made of metal, metal alloy, plastic, or any other suitable material. For example, first portion 113 and second portion 115 may be made of 6062 grade aluminum extrusion. In some embodiments, first portion 113 and second portion 115 are capable of being 3D printed (e.g., additively manufactured). In some embodiments, first portion 113 may be made of a first material and second portion 115 may be made of a second material. In some embodiments, the first material for first portion 113 may be different than the second material for second portion 115. Although base 103 has been discussed as being made up of a first portion 113 and a second portion 115, it will be appreciated that base 103 can be made as one discrete piece.

Continuing to refer to FIGS. 1 and 3, arm 107 extends between a first end 155 and a second end 158. First end 155 may be operatively coupled to connector 110 and second end 158 may be operatively coupled to base 103. For example, second end 158 of arm 107 is coupled to second portion 115 as illustrated in FIG. 3. However, it will be appreciated that arm 107 may be coupled only to first surface 139 of second portion 115 (i.e., on top of base 103). In some embodiments, arm 107 is angled, or offset from the y-axis, to optimize the pitch adjustment (i.e., tilt of connector 110) as will be discussed herein. In some embodiments arm 107 is fixedly coupled to base 103 such that arm 107 is not able to move relative to base 103. In other embodiments, arm 107 is hingedly coupled to base 103 is that arm 107 is able to move in a z-axis (i.e., closer to or away from a user or object).

Arm 107 may be made of metal, metal alloy, plastic, or any other suitable material. For example, arm 107 may be made of 6062 grade aluminum extrusion, which may provide strength and durability for arm 107 to support the heaviest of devices rotating or tilting at the fastest speeds under which the device mount 100 operates. In some embodiments, arm 107 may be capable of being 3D printed (e.g., additively manufactured). In some embodiments, arm 107 may be made of a first material and base 103 may be made of a second material. In some embodiments, the first material for arm 107 may be different than the second material for base 103. Although arm 107 has been discussed as being a piece separate from base 103, it will be appreciated that arm 107 may be fully integrated with base 103 and/or second portion 115 as one discrete piece.

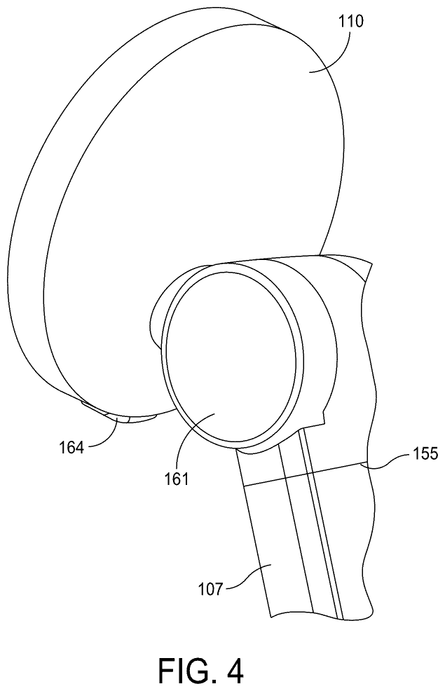

FIG. 4 illustrates a rear isometric view of connector 110 of device mount 100 in accordance with some embodiments. Connector 110 is operatively coupled to first end 155 of arm 107. In some embodiments, connector 110 is hingedly connected, such as with a rotation joint 161, to arm 107 such that connector 110 is able to pivot or tilt. In some embodiments, connector 110 is configured to tilt at least 90 degrees in an up and down motion (i.e., up and down the y-axis). It will be appreciated that connector 110 may also be configured to tilt at least 90 degrees on either side (i.e., about the y-axis) and/or pivot closer to or further away from a user or object (i.e., in the z-axis).

In some embodiments, connector 110 may include a sensor 164, as best illustrated in FIG. 1. In some embodiments, sensor 164 may a button, pressure switch, or some other suitable mechanical sensor that is able to determine if a device is mounted to connector 110. For example, sensor 164 (e.g., a button or pressure switch) may be configured to be mechanically depressed, indicating when a device is mounted to connector 110. In some embodiments, sensor 164 may be a photodetector or some other suitable electrical or light based sensor. For example, when a device is mounted to connector 110 it may block light from reaching sensor 164 (e.g., a photodetector), indicating that a device is mounted to connector 110. Sensor 164 may be configured to activate or deactivate the tracking software (e.g., DockKit software). For example, when a device is mounted to connector 110, sensor 164 is engaged allowing device mount 100 to communicate with a mounted device, and enables the tracking software for the device's camera APIs. Conversely, when a device is removed from connector 110, sensor 164 is disengaged, ending communication between device mount 100 and the device.

Connector 110 may also include a charging circuitry 168 having at least one inductor at least one magnet. When device mount 100 is connected to an AC or DC power source (e.g., external power source or internal battery), connector 110 is configured to provide wireless charging to a device (e.g., mobile phone, tablet, etc.), such as with a wireless charging system disclosed in U.S. Pat. No. 10,062,492 titled “INDUCTION COIL HAVING CONDUCTIVE WINDING FORMED ON A SURFACE OF A MOLDED SUBSTRATE,” which issued on Aug. 28, 2018, the entirety of which is incorporated by reference herein. For example, connector 110 may be configured to provide 15 W fast charge capabilities. In some embodiments, connector 110 may be coupled to a device through temporary adhesive, permanent adhesive, or respective magnets, such as Apple, Inc.'s MagSafe® system. One such example may include coupling a magnet disposed in connector 110 with a respective magnet in the mounted device or with respect to a material to which the magnet is attached. In certain embodiments, high-strength Neodymium magnets are used for limit switches to provide accurate positioning of the device, calibration of the device mount 100, and stability as the device mount 100 is moved (e.g., base 103 rotates and/or connector 110 tilts). A person of ordinary skill in the art will appreciate different ways to provide wireless charging capabilities.

Connector 110 may be made of metal, metal alloy, plastic, silicone, or any other suitable material. For example, connector 110 may be made of silicone to avoid scratches to connector 110 and enhance the magnetic grip. In some embodiments, connector 110 may be capable of being 3D printed (e.g., additively manufactured). In some embodiments, connector 110 may be made of a first material and arm 107 may be made of a second material. In some embodiments, the first material for connector 110 may be different than the second material for arm 107. Although connector has been discussed as being a piece separate from arm 107, it will be appreciated that connector may be fully integrated with arm 107 as one discrete piece.

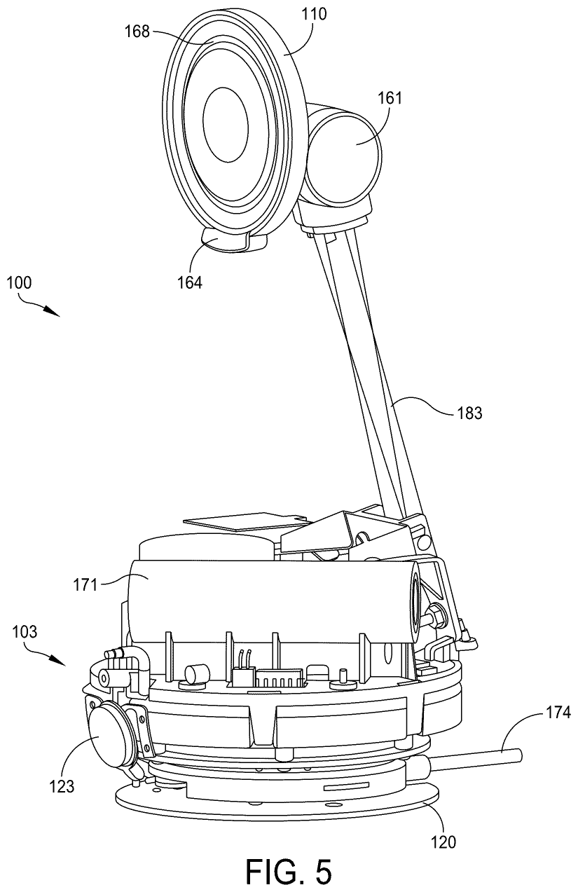

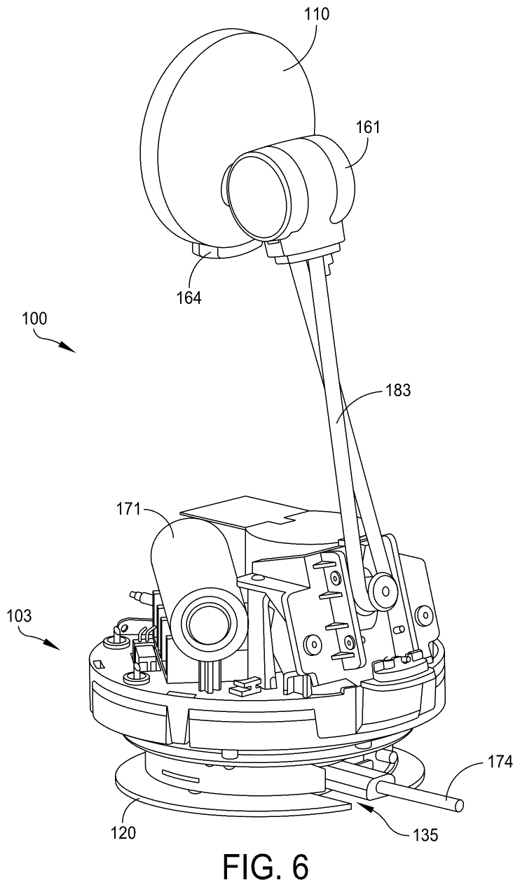

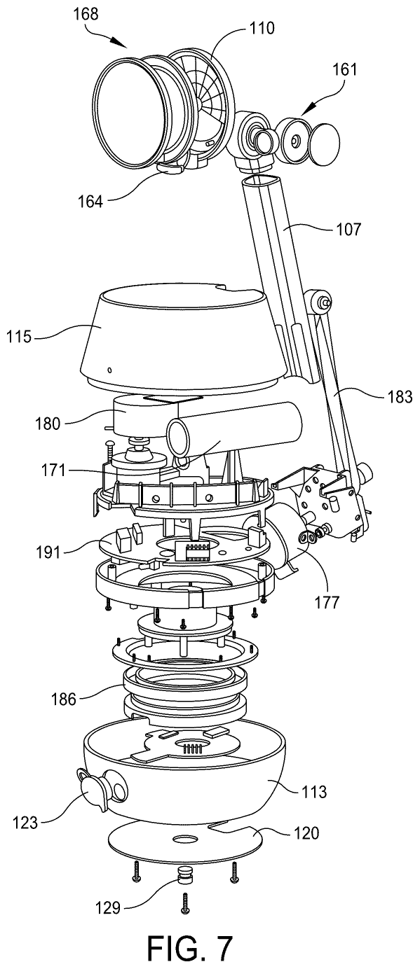

Referring now to FIGS. 5-7, FIGS. 5-6 illustrate isometric views of internal components of device mount 100 and FIG. 7 illustrates an exploded diagram of internal components of device mount 100 in accordance with some embodiments. As discussed above, device mount 100 is configured to move (e.g., rotate, tilt, etc.) a device mounted to connector 110. Power for device mount 100 may from an internal battery 171 disposed within base 103 or from an external power source through port 135. For example, device mount 100 may be coupled to a power source with chord 174. In some embodiments, battery 171 is rechargeable, and an external power source (e.g., AC plug in through port 135) may also be used to charge battery 171. In some embodiments, battery 171 has integrated under-voltage, over-voltage, and temperature protection, which allows device mount 100 to have a better battery life and longevity.

As best seen in FIG. 7, device mount 100 includes a first motor 177 and a second motor 180 disposed within base 103. First motor 177 may be configured to provide the tilt motion for connector 110 in an up and down direction (i.e., along the y-axis). Second motor 180 may be configured to provide the rotation motion for base 103 (i.e., about the y-axis). First motor 177 and second motor 180 may be any suitable motor, such as a stepper motor. For example, stepper motors allow for a low gear ratio and high-performance magnetic array to maintain stability and secure positioning regardless of whether device mount 100 is “on” or “off.” Meaning, that even if device mount 100 is turned “off,” the stepper motor of at least first motor 177 prevents the mounted device coupled to connector 110 from falling on itself from the weight of the mounted device. In some embodiments, first motor 177 and second motor 180 are not visible to a camera of the mounted device.

Device mount 100 may further include one or more bands 183 disposed within arm 107 and operatively coupled to first motor 177 and rotation joint 161. For example, the one or more bands 183 may include one or more teeth to precisely control the pitch (i.e., tilt) of the connector 110. When first motor 177 is in operation, the one or more bands 183 moves to rotate the rotation joint 161 to tilt the connector 110. It will be appreciated that the one or more bands 183 may not include teeth, and may be a drive belt. The one or bands 183 may be made of any suitable material, such as plastic, nylon, or some other self-lubricating material, such as Delrin® Acetal Homopolymer (Polyoxymethylene) available from Delrin USA, LLC, may be used.

Second motor 180 may be operatively coupled to a shaft disposed within base 103 such that operation of second motor 180 causes rotation of the base 103. However, it will be appreciated that second motor 180 can be configured to rotate the second portion 115 relative to the first portion 113 or to rotate the first portion 113 relative to the second portion 115. Base 103 (or second portion 115) is configured to rotate in a full 360 degrees. However, it will be appreciated that base 103 could include a limit to prevent rotation in a full 360 degrees. In some embodiments, one or more bearings 186 may be used to facilitate smooth, accurate, and stable rotation. For example, the one or more bearings 186 may be a 65 mm stainless steel bearing. However, a person of ordinary skill in the art will appreciate other suitable bearings that may be used.

In some embodiments, second motor 180 may also be coupled to one or more bands (or gears), similar to band 183, for high precision, low friction, longevity, max payload considerations, torque, and speed of second motor 180. For example, the one or more bands may include one or more teeth to precisely control the rotation of the base 103. When second motor 180 is in operation, the one or more bands moves to rotate the base 103. It will be appreciated that the one or more bands may not include teeth, and may be a drive belt. The one or bands may be made of any suitable material, such as plastic, nylon, or some other self-lubricating material, such as Delrin®, may be used.

In some embodiments, first motor 177 and second motor 180 are controlled by smart algorithms conducted by the device mount 100 and/or the tracking software run on the mounted device to determine the best speed for rotation for movement tracking. In certain embodiments, a controller for first motor 177 and second motor 180 is configured, such as through firmware, to ensure smoothness and optimal speed for rotation and tilt during tracking.

Referring to FIG. 7, device mount 100 may also include a communications circuit 191 to wirelessly connect to a device coupled to connector 110. For example, communications circuit 191 may be configured to provide wireless communication between device mount 100 and a device through Near-field communication (NFC), Bluetooth, Wi-Fi, ad-hoc wireless network, or any other suitable wireless communication as will be further discussed below. In some embodiments, device mount 100 and/or the device has a single user pairing history. In other embodiments, device mount 100 and/or the device has multiple user pairing history.

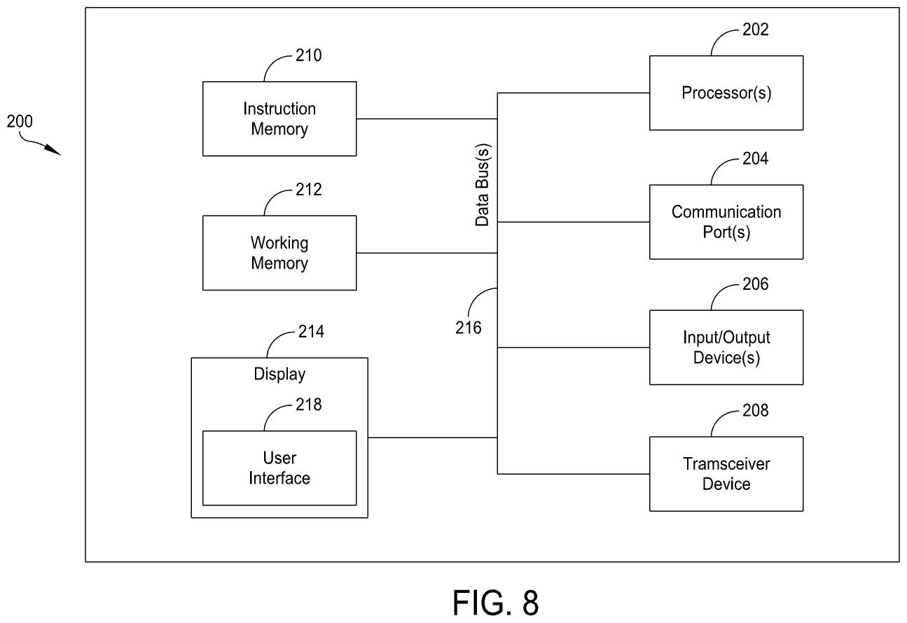

FIG. 8 is a block diagram of an example computing device 200 in accordance with some embodiments. The device 200 that can be employed by a disclosed system or used to execute a disclosed method. Device 200, such as device mount 100, or device 300 as discussed in more detail below, can implement, for example, one or more of the functions described herein. It should be understood, however, that other device configurations are possible.

Device 200 can include one or more processors 202, one or more communication port(s) 204, one or more input/output devices 206, a transceiver 208, instruction memory 210, working memory 212, and optionally a display 214, all operatively coupled to one or more data buses 216. Data buses 216 allow for communication among the various devices, processor(s) 202, instruction memory 210, working memory 212, communication port(s) 204, and/or display 214. Data buses 216 can include wired, or wireless, communication channels. Data buses 216 are connected to one or more devices.

Processor(s) 202 can include one or more distinct processors, each having one or more cores. Each of the distinct processors can have the same or different structures. Processor(s) 202 can include one or more central processing units (CPUs), one or more graphics processing units (GPUs), application specific integrated circuits (ASICs), digital signal processors (DSPs), and the like.

Processor(s) 202 can be configured to perform a certain function or operation by executing code, stored on instruction memory 210, embodying the function or operation of the device mount 100 or device 300 discussed below. For example, processor(s) 202 can be configured to perform one or more of any function, method, or operation disclosed herein.

Communication port(s) 204 can include, for example, a serial port such as a universal asynchronous receiver/transmitter (UART) connection, a Universal Serial Bus (USB) connection, lightning connection, USB-C connection, micro-USB connection, or any other suitable communication port or connection. In some examples, communication port(s) 204 allows for the programming of executable instructions in instruction memory 210. In some examples, communication port(s) 204 allow for the transfer, such as uploading or downloading, of data.

Input/output devices 206 can include any suitable device that allows for data input or output. For example, input/output devices 206 can include one or more of a keyboard, a touchpad, a mouse, a stylus, a touchscreen, a physical button, a speaker, a microphone, or any other suitable input or output device.

Transceiver 208 can allow for communication with a network, such as a Wi-Fi network, an Ethernet network, a cellular network, Bluetooth network, or any other suitable communication network. For example, if operating in a cellular network, transceiver 208 is configured to allow communications with the cellular network. Processor(s) 202 is operable to receive data from, or send data to, a network via transceiver 208.

Instruction memory 210 can include an instruction memory 210 that can store instructions that can be accessed (e.g., read) and executed by processor(s) 202. For example, the instruction memory 210 can be a non-transitory, computer-readable storage medium such as a read-only memory (ROM), an electrically erasable programmable read-only memory (EEPROM), flash memory, a removable disk, CD-ROM, any non-volatile memory, or any other suitable memory with instructions stored thereon. For example, the instruction memory 210 can store instructions that, when executed by one or more processors 202, cause one or more processors 202 to perform one or more of the operations of device mount 100 or device 300.

In addition to instruction memory 210, the computing 200 can also include a working memory 212. Processor(s) 202 can store data to, and read data from, the working memory 212. For example, processor(s) 202 can store a working set of instructions to the working memory 212, such as instructions loaded from the instruction memory 210. Processor(s) 202 can also use the working memory 212 to store dynamic data created during the operation of device 200. The working memory 212 can be a random access memory (RAM) such as a static random access memory (SRAM) or dynamic random access memory (DRAM), or any other suitable memory.

Display 214 is configured to display user interface 218. User interface 218 can enable user interaction with device 200. In some examples, a user can interact with user interface 218 by engaging input/output devices 206. In some examples, display 214 can be a touchscreen, where user interface 218 is displayed on the touchscreen.

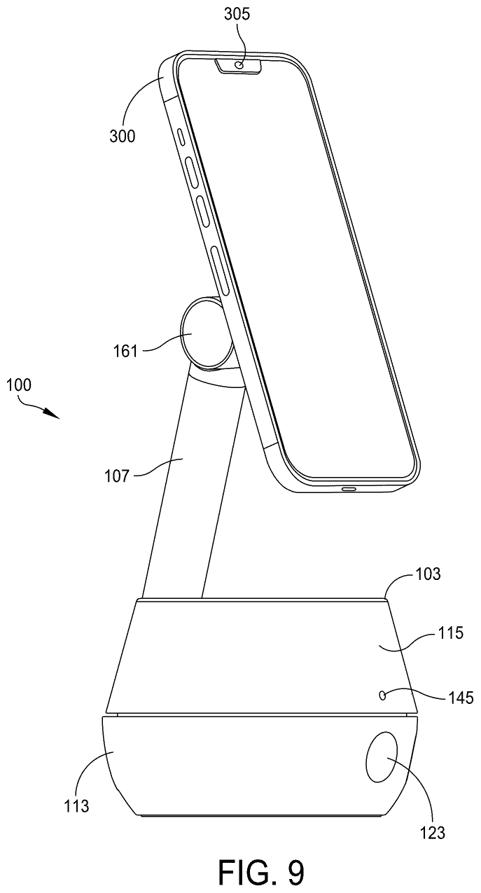

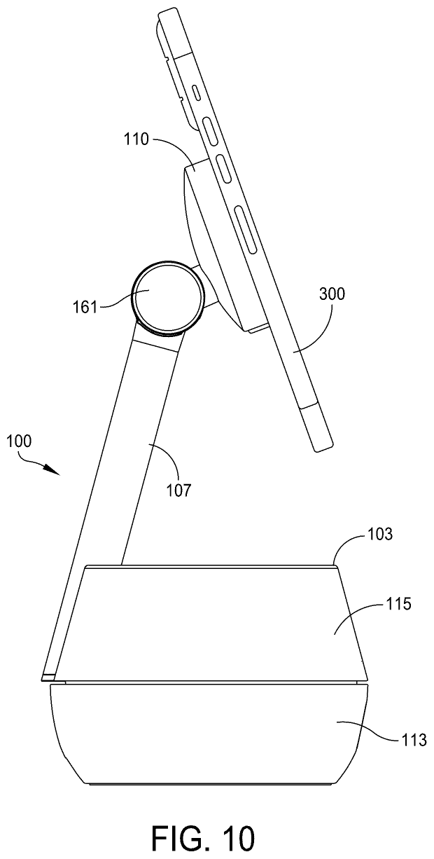

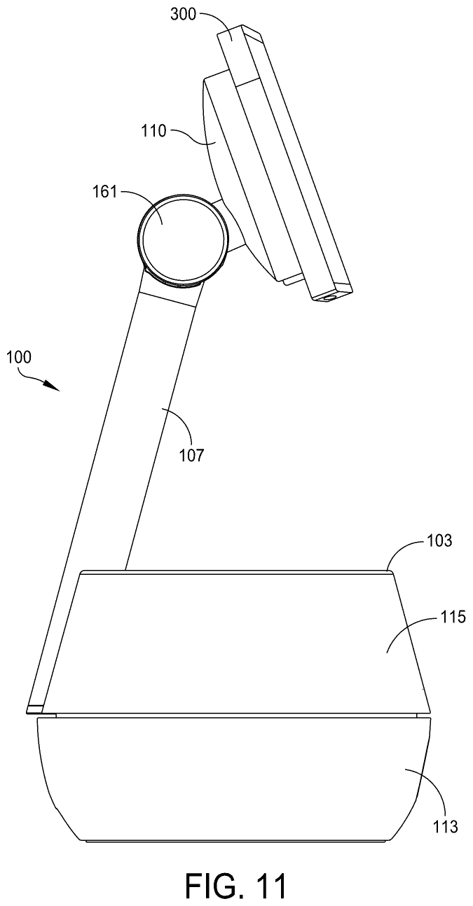

FIGS. 9-12 illustrate a device 300 coupled to a device mount 100 in accordance with some embodiments. As discussed herein, device 300, such as a mobile phone, tablet, etc., can be coupled to device mount 100 with connector 110. In some embodiments, device 300 will include at least one front camera 305 and at least one back camera 310a-c. Device mount 100 and connector 110 are configured to retain device 300 in a vertical orientation, or portrait, as illustrated in FIGS. 9-10. Device mount 100 and connector 110 are also configured to retain device 300 in a horizontal orientation, or landscape, as illustrated in FIG. 11. It will be appreciated that either the at least one front camera 305 or one of the back camera's 310a-c may be used by the tracking software to track a user or object in view of the camera 305.

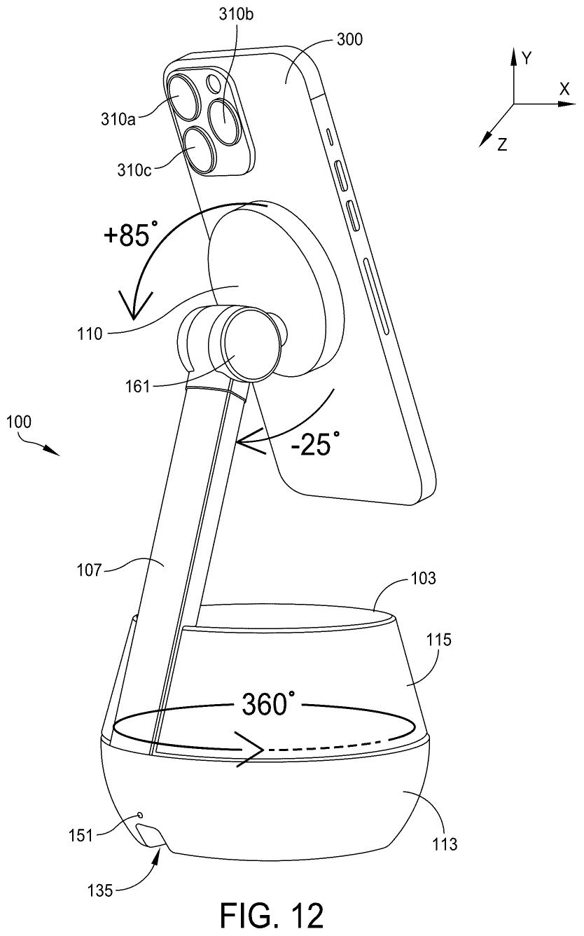

FIG. 12 illustrates exemplary movement capabilities of device mount 100 in accordance with some embodiments. Using tracking software, such as DockKit, device mount 100 can be used with device's 300 camera APIs to track a user or object as it moves relative to device mount 100. For example, device 300, when coupled to device mount 100, can use the tracking software to control device mount 100 to rotate base 103 and/or tilt connector 110 to keep track of the user or object. For example, connector 110 is configured to tilt up and down (i.e., along the y-axis) using first motor 177 and at least one band 183. In some embodiments, device mount 100 is configured to tilt connector 110 and device 300 in the up direction at least 85 degrees and in the down direction at least 25 degrees as illustrated in FIG. 12. Additionally, base 103 (as a whole), first portion 113, or second portion 115 is configured to rotate using second motor 180 and one or more bearings 186. In some embodiments, base 103, first portion 113 or second portion 115 can rotate a full 360 degrees.

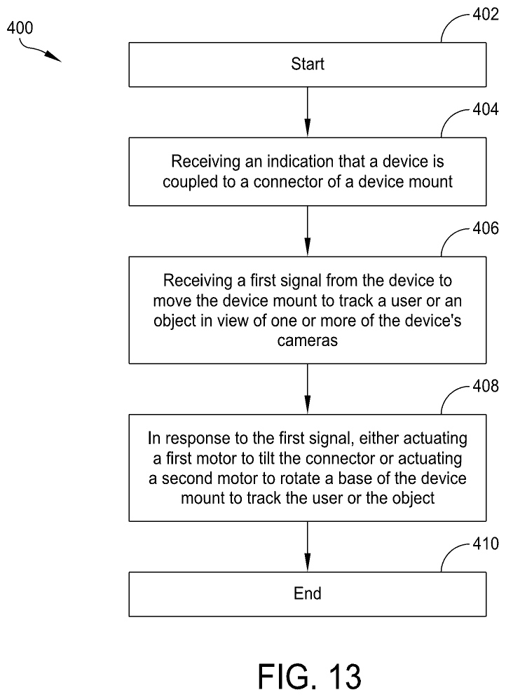

FIG. 13 illustrates an exemplary method 400 of using device mount 100 in accordance with some embodiments. Method 400 may start at step 402, and may include step 404, which comprises receiving an indication that a device 300 is coupled to a connector 110 of a device mount 100. For example, when device 300 is coupled to connector 110, sensor 164 is engaged and initiates a signal to indicate that device 300 is coupled to connector 110. Method 400 may also include step 406, which comprises receiving a first signal from the device 300 to move the device mount 100 to track a user or an object in view of one or more of the device's 300 cameras 305, 310a-c. For example, the tracking software running on device 300 may cause the device 300 to send a signal to device mount 100 to move in order to maintain track on the user or the object. Method 400 may also include step 408, which comprises in response to the first signal, either actuating a first motor 177 to tilt the connector 110 or actuating a second motor 180 to rotate a base 103 of the device mount 100 to track the user or the object. For example, in response to the signal from the device 300, through tracking software, either the first motor 177 operatively coupled to the connector 110 or the second motor 180 operatively coupled to the base 103 will actuate in order to maintain track of the user or the object. Method 400 may end at step 410.

In some embodiments, method 400 may also include receiving a second signal from the device 300 to move the device mount 100 to track the user or the object in view of one or more of the device's 300 cameras 305, 310a-c. For example, the tracking software running on device 300 may cause the device 300 to send a second signal to device mount 100 to move in order to maintain track on the user or the object. In some embodiments, method 400 may also include in response to the second signal either actuating the first motor 177 to tilt the connector 110 or actuating the second motor 180 to rotate the base 103 of the device mount 100 to track the user or the object. For example, in response to the signal from the device 300, through tracking software, either the first motor 177 operatively coupled to the connector 110 or the second motor 180 operatively coupled to the base 103 will actuate in order to maintain track of the user or the object. In some embodiments, the first signal and the second signal are different. For example, the first signal may cause actuation of the first motor 177 to tilt connector 110 and the second signal may cause actuation of the second motor 180 to rotate the base 103. In some embodiments, the first signal and the second signal are the same. For example, the first signal and the second signal may both cause actuation of the first motor 177 to tilt the connector 110 or both cause actuation of the second motor 180 to rotate the base 103. It will be appreciated that method 400 is not limited to a first signal and a second signal, and that a plurality of signals may be transmitted over an extended period of time while device mount 100 and the tracking software on device 300 are in operation to track a user or an object with one or more of device's 300 cameras 305, 310a-c.

In addition, the methods, apparatuses, devices, and systems described herein can be at least partially embodied in the form of computer-implemented processes and apparatus for practicing those processes. The disclosed methods may also be at least partially embodied in the form of tangible, non-transitory machine-readable storage media encoded with computer program code. For example, the steps of the methods can be embodied in hardware, in executable instructions executed by a processor (e.g., software), or a combination of the two. The media may include, for example, RAMs, ROMs, CD-ROMs, DVD-ROMs, BD-ROMs, hard disk drives, flash memories, or any other non-transitory machine-readable storage medium. When the computer program code is loaded into and executed by a computer, the computer becomes an apparatus for practicing the method. The methods may also be at least partially embodied in the form of a computer into which computer program code is loaded or executed, such that, the computer becomes a special purpose computer for practicing the methods. When implemented on a general-purpose processor, the computer program code segments configure the processor to create specific logic circuits. The methods may alternatively be at least partially embodied in application specific integrated circuits for performing the methods.

In this application, including the definitions below, the term “module” or the term “controller” may be replaced with the term “circuit.” The term “module” may refer to, be part of, or include processor hardware (shared, dedicated, or group) that executes code and memory hardware (shared, dedicated, or group) that stores code executed by the processor hardware.

The module may include one or more interface circuits. In some examples, the interface circuit(s) may implement wired or wireless interfaces that connect to a local area network (LAN) or a wireless personal area network (WPAN). Examples of a LAN are Institute of Electrical and Electronics Engineers (IEEE) Standard 802.11-2016 (also known as the WIFI wireless networking standard) and IEEE Standard 802.3-2015 (also known as the ETHERNET wired networking standard). Examples of a WPAN are the BLUETOOTH wireless networking standard from the Bluetooth Special Interest Group and IEEE Standard 802.15.4.

The module may communicate with other modules using the interface circuit(s). Although the module may be depicted in the present disclosure as logically communicating directly with other modules, in various implementations the module may actually communicate via a communications system. The communications system includes physical and/or virtual networking equipment such as hubs, switches, routers, and gateways. In some implementations, the communications system connects to or traverses a wide area network (WAN) such as the Internet. For example, the communications system may include multiple LANs connected to each other over the Internet or point-to-point leased lines using technologies including Multiprotocol Label Switching (MPLS) and virtual private networks (VPNs).

In various implementations, the functionality of the module may be distributed among multiple modules that are connected via the communications system. For example, multiple modules may implement the same functionality distributed by a load balancing system. In a further example, the functionality of the module may be split between a server (also known as remote, or cloud) module and a client (or, user) module.

The term machine learned model, as used herein, includes data models created using machine learning. Machine learning, according to the present disclosure, may involve putting a model through supervised or unsupervised training. Machine learning can include models that may be trained to learn relationships between various groups of data. Machine learned models may be based on a set of algorithms that are designed to model abstractions in data by using a number of processing layers. The processing layers may be made up of levels of trainable filters, transformations, projections, hashing, pooling, and regularization. The models may be used in large-scale relationships-recognition tasks. The models can be created by using various open-source and proprietary machine learning tools known to those of ordinary skill in the art.

The foregoing is provided for purposes of illustrating, explaining, and describing embodiments of these disclosures. Modifications and adaptations to these embodiments will be apparent to those skilled in the art and may be made without departing from the scope or spirit of these disclosures.

It may be emphasized that the above-described embodiments, particularly any “preferred” embodiments, are merely possible examples of implementations, merely set forth for a clear understanding of the principles of the disclosure. Many variations and modifications may be made to the above-described embodiments of the disclosure without departing substantially from the spirit and principles of the disclosure. All such modifications and variations are intended to be included herein within the scope of this disclosure.

While this specification contains many specifics, these should not be construed as limitations on the scope of any disclosures, but rather as descriptions of features that may be specific to a particular embodiment. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A device mount comprising:
a base;
an arm coupled to the base;
a connector coupled to the arm with a rotation joint;
a first motor disposed within the base and configured to tilt the connector, facilitated by the rotation joint; and
a second motor disposed within the base and configured to rotate the base.

2. The device mount of claim 1, further comprising a band disposed within the arm that is operatively coupled to the first motor and the rotation joint such that actuation of the first motor tilts the connector.

3. The device mount of claim 2, wherein the band is made of self-lubricating nylon.

4. The device mount of claim 1, further comprising a stabilizing member.

5. The device mount of claim 4, wherein the stabilizing member is a threaded hole configured to receive a threaded fastener on a tripod.

6. The device mount of claim 1, wherein the base further comprises an operator configured to turn power to the device mount on and off.

7. The device mount of claim 1, further comprising one or more lights configured to convey status information.

8. The device mount of claim 1, wherein the connector includes a sensor configured to detect when a device is mounted to the connector.

9. The device mount of claim 1, wherein the connector is configured to wirelessly charge a device.

10. The device mount of claim 1, wherein the first motor and the second motor are configured to be actuated by a tracking software running on a device mounted to the connector.

11. The device mount of claim 1, further comprising an internal battery and a port configured to receive a power cord from an external power source.

12. A device mount comprising:
a base comprising a first portion and a second portion;
an arm coupled to the base;
a connector coupled to the arm with a rotation joint;
a first motor disposed within the base and configured to tilt the connector, facilitated by the rotation joint; and
a second motor disposed within the base and configured to rotate the second portion of the base.

13. The device mount of claim 12, further comprising a band disposed within the arm that is operatively coupled to the first motor and the rotation joint such that actuation of the first motor tilts the connector.

14. The device mount of claim 13 wherein the band is made of self-lubricating nylon.

15. The device mount of claim 12, further comprising one or more lights configured to convey status information.

16. The device mount of claim 12, wherein the connector includes a sensor configured to detect when a device is mounted to the connector.

17. The device mount of claim 12, wherein the connector is configured to wirelessly charge a device.

18. The device mount of claim 12, wherein the first motor and the second motor are configured to be actuated by a tracking software running on a device mounted to the connector.

19. A method comprising:
receiving an indication that a device is coupled to a connector of a device mount;
receiving a first signal from the device to move the device mount to track a user or an object in view of one or more of the device's cameras; and
in response to the first signal, either actuating a first motor to tilt the connector or actuating a second motor to rotate a base of the device mount to track the user or the object.

20. The method of claim 19, further comprising:
receiving a second signal from the device to move the device mount to track the user or the object in view of one or more of the device's cameras; and
in response to the second signal, either actuating the first motor to tilt the connector or actuating the second motor to rotate the base of the device mount to track the user or the object.
